(19) United States
(12) Patent Application Publication
(10) Pub. No.: US 2002/0151113 A1
(43) Pub. Date: Oct. 17, 2002

(54) Apparatus and method for suppressing false resonances in fiber optic modulators

(76) Inventors: Henry H. Hung, Phoenix, AZ (US); Yellapu Anjan, Scottsdale, AZ (US); Majid Malakia, Scottsdale, AZ (US)

Correspondence Address: Tod R. Nissle, Esq., TOD R. NISSLE, P.C., P.O. Box 55630, Phoenix, AZ, 85078, US

(21) Appl. No.: 09/835,210

(22) Filed: Apr. 13, 2001

(51) Int. Cl. H01L 21/44; H01L 21/48; G02B 6/36

(52) U.S. Cl. 438/127; 385/92; 385/94

(57) ABSTRACT

An apparatus and method for suppressing false resonances in fiber optic modulators forms cavities in the modulator housing and fills the cavities with a flowable composition that includes iron.

This invention relates to a method and apparatus for minimizing false resonances in fiber optic modulators and other optical circuits.

A fiber optic modulator is an integrated optic chip device. An integrated optic chip (IOC) is made of an electro-optic material whose index of refraction increases or decreases depending on the direction of electric field applied to it. IOC's are analogous to integrated circuits (IC's) utilized in semiconductor technology. The signal processing in an IC is totally electric whereas in an IOC it is both optical and electrical. The term “integrated” in “integrated optic chip” implies that the chip has both electrical and optical parts. One or more external electrical signal(s) is applied to one or more electrodes formed on an IOC and the electrical signals change the index of refraction of one or more waveguides adjacent to the electrodes. Changing the index of refraction of a waveguide produces a concomitant change in the intensity and/or phase of light passing through the waveguide. An IOC device is a device which includes one or more IOCs.

An optical circuit is a circuit which includes one or more IOCs or which transmits light through a solid material that comprises part of the circuit.

Fiber optic modulators ordinarily are enclosed in and protected by a housing. Electromagnetic fields inside the housing can cause false, undesired resonances to be created inside the housing. There are at least two causes of such resonances.

The first cause is higher-order EM mode propagation on the electrode structure. For a one millimeter thick LiNbO₃ crystal, such propagation primarily occurs above 20 GHz for a coplanar waveguide (CPW) and above 10 GHz for a coplanar strip waveguide (CSW). The frequency at which higher-order EM (electromagnetic) mode propagation begins can be increased by thinning the LiNbO₃ crystal. For example, a fiber optic modulator designed for 10 Gb/S operation with CPW electrodes can be made on a one millimeter thick LiNbO₃ crystal without producing an undesired resonance.

The second cause is the presence of EM (electromagnetic) cavities with the metallic container used to house and protect a fiber optic modulator. The electrodes and especially the regions where transitions are made, typically radiate EM power. This radiated power results in resonances at frequencies related to the internal package features. For example, false resonances are created when RF signals travel and transition from components to the modulator and from the modulator to components. RF signals transition from a package connector pin through a wire or other connector to a microstrip (planar conductor) on the modulator and transition from the microstrip through a wire or other connector to the modulator. During these transitions, false resonances are produced. These false resonances emanate through the modulator and the modulator packaging and create an electromagnetic field. The electromagnetic field interferes with the passage of light through the modulator and alters the light. Exactly how the light is changed does not appear to be known with certainty. The electromagnetic field may also alter the wavelength or frequency of light passing through the modulator. Regardless of how the electromagnetic field alters the light, the fact that the light has been altered is demonstrated because at least one of the physical characteristics of light output from the modulator changes. Presently, it is RF signals that cause undesired resonances. DC signals traveling into a modulator are not believed to produce or result in significant undesired resonances.

Accordingly, it would be highly desirable to provide a method and apparatus for minimizing the generation of undesired resonances in the container that houses a fiber optic modulator or other optical circuit.

Therefore, it is a principal object of the invention to provide an improved method and apparatus for minimizing the formation of undesired resonances either in an optical circuit or in the housing in which the optical circuit is mounted.

These and other, further and more specific objects and advantages of the invention will be apparent to those skilled in the art from the following detailed description thereof, taken in conjunction with the drawings, in which:

FIG. 1 is a top view illustrating a solid microwave attenuation material utilized in accordance with the invention;

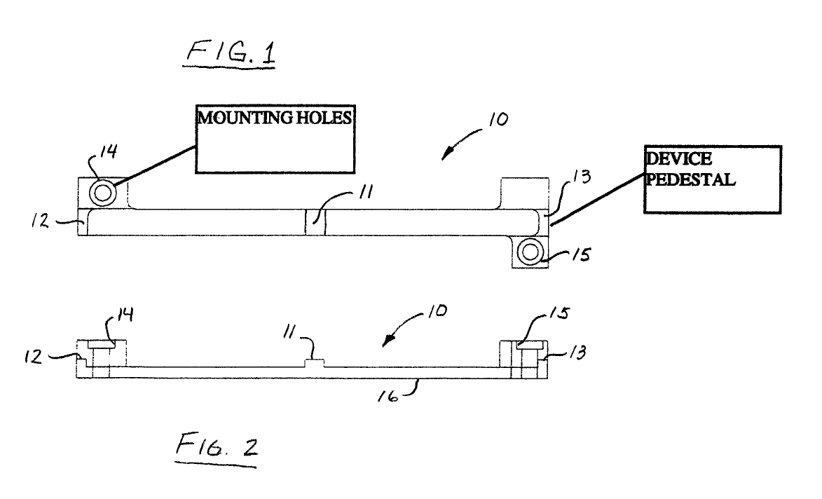

FIG. 2 is a front view further illustrating the microwave attenuation material of FIG. 1;

FIG. 3 is an exploded view illustrating a modulator housing constructed in accordance with the principles of the invention; and,

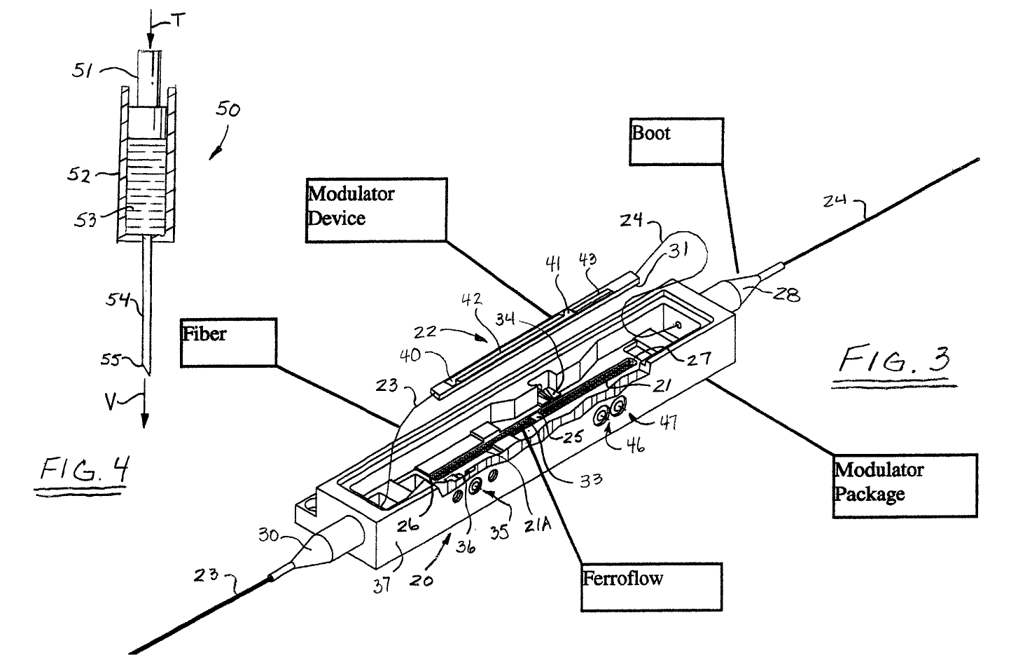

FIG. 4 is a side section view illustrating a syringe assembly used in accordance with the invention.

Briefly, in accordance with the invention, I provide an improved method for minimizing the formation of frequency responses in packaging for at least one integrated optic chip modulator. The packing includes at least one cavity adjacent the modulator. The improved method includes the step of filling the cavity with a flowable microwave absorber.

In another embodiment of the invention, I provide an improved method for minimizing the formation of frequency responses in packaging for at least one integrated optic chip modulator. The packing includes at least one microwave absorber adjacent the modulator.

Turning now to the drawings, which depict the presently preferred embodiments of the invention for the purpose of illustrating the practice thereof, and in which like reference characters refer to corresponding elements throughout the several views, FIGS. 1 and 2 illustrate a modulator support member 10 machined or otherwise cut out of a solid block of a material consisting of carbonyl iron spheres dispersed in an epoxy resin. This material is available under the FERROSORB trademark from Microwave Filter Company, Inc.

Member 10 includes pedestals 11, 12, 13 upon which a modulator 22 is set. Mounting holes 14, 15 are used to secure member 10 in the bottom 20 of a stainless steel, aluminum or other metal housing which, when assembled, encloses and protects the modulator 22. The bottom 20 in FIG. 3 generally illustrates one kind of housing bottom used for a modulator 22. The shape and dimension of bottom 20 can be altered as desired. FIG. 3 does not show member 10 mounted in bottom 20.

After member 10 is secured in the bottom of a housing by directing pins or other fasteners through mounting holes 14 and 15, a modulator 22 is mounted on member 10 by using silicone RTV or another desired adhesive between the bottom 31 of modulator 22 and each of pedestals 11, 12, 13. The silicone RTV firmly holds modulator 22 in place, but compensates for and allows for the difference in the rate of thermal expansion between modulator 22 and member 10. Since member 10 is long and narrow, it may bow in the center, raising pedestal 11 higher than pedestals 12 and 13. This can be compensated for by using a thicker layer of silicone RTV on pedestals 12, 13 than on pedestal 11. One disadvantage of the FERROSORB material is that it is brittle.

In the embodiment of the invention illustrated in FIG. 3, bottom 20 includes long, narrow rectangular grooves 21, 21A which are positioned directly beneath modulator 22 when modulator 22 is mounted on and adhered to pedestals 25, 26, 27 with Norland 123 UV epoxy or with another adhesive or fastening material. Prior to mounting modulator 22 on pedestals 25, 26, 27, grooves 21A, 21 are each filled with a viscous liquid composition 33 comprising carbonyl iron spheres in an epoxy resin. This composition cures and solidifies after it is used to fill grooves 21, 21A. One carbonyl iron—epoxy resin composition is sold as FERROFLOW by the Microwave Filter Company, Inc. While FERROFLOW is presently preferred in the practice of the invention, other polymer-metal compositions can be utilized. For example, various types of iron spheres or powder can be intermixed with various types of polymers and readily tested to determine if the desired resonance absorption is achieved. Other magnetic metals or non-magnetic metals can be utilized in a polymer composition or other composition to dampen, break up, or otherwise affect undesirable resonances.

One advantage of the bottom 20 is that the pedestals 25, 26, 27 are machined into bottom 20 and provide firm support for modulator 22. This support prevent movement of modulator 22 during wire bonding which makes it more likely that the wire bonding will not be defective. Another advantage of bottom 20 is that a UV epoxy can be used to bond modulator 22 to pedestals 25, 26, 27. The UV epoxy cures in seconds. The silicone RTV requires twenty-four hours to cure.

Optic fiber 23 extends through boot 30 into bottom 20 to the input end of modulator 22. Optic fiber 24 extends through boot 28 into bottom 20 to the output end of modulator 22.

Pin 35 is mounted in the wall 37 of bottom 20. Pin 35 extends through wall 20 and is connected to a microstrip 36. Microstrip 36 comprises a flat electrode plate. When modulator 22 is mounted in bottom 20, microstrip 36 is connected to modulator 22. A lead (not shown) is attached to pin 35 and delivers RF signals to pin 35. The RF signals are transmitted to via pin 35 and microstrip 36 to modulator 22. Microstrip 36 is typically presently about six microns thick. Microstrip 36 can, if desired, include a pair of auxiliary separate flat electrode plates spaced apart from and adjacent to microstrip 36. The auxiliary electrode plates serve as ground plates and are connected to modulator 22. When microstrip 36 and the auxiliary elecctrode plates are provided and each connected to modulator 22, the modulator 22 is termed a coplanar waveguide (CPW). When only microstrip 36 is provided and the auxiliary ground plates are not utilizes, the modulator 22 is termed a coplanar strip waveguide (CSW).

After modulator 22 is mounted in bottom 20, a top (not shown) is sealingly connected to bottom 20 to enclose and seal modulator 22 in bottom 20. Bottom 20 and the top attached to bottom 22 are preferably fabricated from stainless steel or some other metal.

The modulator 22 is sometimes called a “chip” by those of skill in the art, and the combination of modulator 22—bottom 20 and the top sealingly attached to bottom 20 is termed the “modulator”.

Modulator 22 includes a thin elongate electrode 42 which carries the RF signal transmitted to modulator via pin 35 and microstrip 36. Electrode 42 is positioned intermediate ground electrodes 40 and 41. The RF signal which travels along electrode 42 exits via microstrip 34 to a terminal (not shown). Microstrip 36 includes a pair of flat electrode plates (not shown) each of which is connected to one of the ground plates 40, 41. Similarly, microstrip 34 includes a pair of flat electrode plates each of which is connected to one of the ground plates 40, 41. In the practice of the invention, it is believed critical to have ferroflow beneath or above the RF electrodes 40-42. Positioning ferroflow to either side of modulator 22 does not appear to be effective in minimizing false resonances. Ferroflow can also be positioned under or above the DC electrodes on the top of modulator 22.

Modulator also includes DC electrode 43. Electrode 43 receives a DC signal which enters via pin 46. The DC signal from pin 46 travels along electrode 43 and exits via pin 47.

In use, the bottom 20 of the modulator housing is produced and includes cavities or grooves 21, 21A (FIG. 3) which are positioned beneath modulator 22 when modulator 22 is mounted on and adhered to pedestals 25, 26, 27. A syringe 50 (FIG. 4) is charged with a viscous liquid composition 53 comprising carbonyl iron spheres in an epoxy resin. The syringe 50 is positioned over a groove 21, 21A with the tip 55 of needle 54 positioned adjacent groove 21, 21A. A force is pneumatically, hydraulically, or otherwise generated to displace plunger 51 in the direction of arrow T to force liquid composition 53 out through hollow needle 55 in the direction of arrow V into groove 21, 21A. While plunger 51 is forced in the direction of arrow T the tip 55 of needle 54 is simultaneously moved along groove 21, 21A such that composition 53 is evenly distributed in and fills groove 21, 21A. When the composition 53 is FERROFLOW (TM), the composition hardens in about 20 minutes. Pedestals 11, 12, 13 are shaped and dimensioned such that after grooves 21, 21A are filled and the modulator 22 is set on pedestals 11, 12, 13, there is a small space between modulator 22 and the FERROFLOW in grooves 21, 21A. Ideally, as small of a space as possible between the FERROFLOW and modulator 22 is desired as long as the modulator 22 does not contact the FERROFLOW. After the FERROFLOW hardens, an epoxy or other adhesive is utilized to secure the modulator 22 to pedestals 11, 12, 13. The ends of fibers 23, 24 are inserted through apertures in the wall of bottom 20 and are pigtailed to the modulator 22. Fibers 23, 24 are sealed in the apertures in the walls of bottom 20. Modulator 22 is connected to the microstrips 34, 36 and to the microstrip associated with pins 46 and 47. The top (not shown) of the modular housing is sealingly fixedly connected to bottom 20 using solder, adhesive, screws, or any other desired fastening means.

Having described my invention in such terms as to enable those skilled in the art to understand and practice the invention, and having described the presently preferred embodiments thereof, I claim:

1. A method of minimizing the formation of frequency responses in packaging for at least one integrated optic chip modulator, said packaging including at least one cavity adjacent the modulator, the method including the steps of
(a) filling the cavity with a flowable microwave absorber; and,
(b) permitting the absorber to harden.

2. A method of minimizing the formation of frequency responses in packaging for at least one integrated optic chip modulator, said method including the steps of
(a) forming a housing with cavities;
(b) applying a liquid microwave absorber in the cavities; and,
(c) mounting the modulator in the housing adjacent the microwave absorber.
